(19) United States
(12) Patent Application Publication
(10) Pub. No.: US 2007/0229103 A1
(43) Pub. Date: Oct. 4, 2007

(54) Socket, a circuit component having the socket and an information processing system having the circuit component

(75) Inventor: Michitaka Tani, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/489,632

(22) Filed: Jul. 20, 2006

(30) Foreign Application Priority Data
Mar. 31, 2006 (JP) 2006-096889

(51) Int. Cl. G01R 31/02

(52) U.S. Cl. 324/755

(57) ABSTRACT

A socket for mounting an IC device having an opening formed in the socket body is disclosed. At least a probe in electrical contact with the IC device is partly exposed to the opening and cooled by cooling air passing through the opening.

### BACKGROUND OF THE INVENTION

1. Field of the Invention

This invention relates to a socket to mount an IC (integrated circuit) device thereon, a circuit component having the socket and an information processing system having the circuit component.

2. Description of the Related Art

In the prior art, the current conduction test of an IC or a LSI device is carried out using a socket on which the device can be mounted and which is connected to a power supply and a signal source. In order to prevent the device from being overheated, heat is radiated from the underside of the socket with the device mounted thereon or the top face of the device is cooled with air or a liquid.

In recent years, an increase in an integration degree of semiconductor chips included in the device and an increase in a clock speed has increased the current flowing in the device. In an IC device such as a power semiconductor device consuming a large amount of power, therefore, a temperature increases during the device operation so greatly as to make heat control of the device difficult. When the characteristics of the IC device are measured while cooling the device, the IC device is required to be cooled efficiently. For this reason, efficient heat radiation from the IC socket is required.

In the prior art, the provision of a radiation means on an element to mount a device has been proposed to efficiently radiate the heat from the IC device (Japanese Unexamined Patent Publication No. 11-233698 (Patent Document 1), Japanese Unexamined Patent Publication No. 2001-189412 (Patent Document 2), Japanese Unexamined Patent Publication No. 9-245916 (Patent Document 3)).

Patent Document 1 discloses a semiconductor package lid for conducting the heat from a semiconductor die to a heat sink, in which a heat pipe is built in the portion of the semiconductor package lid intermediate between the semiconductor die and the heat sink. Patent Document 2 discloses that radiation fins whereby the heat generated by a semiconductor chip mounted on a module board is released outside are connected, through a radiation sheet in contact with the semiconductor chip, to the upper part of a block socket sandwiching the module board. Further, Patent Document 3 discloses that radiation fins are arranged on at least one of the outer surfaces of the reinforcing metal member mounted on the side surface of a socket body.

These conventional devices have radiation members such as independent radiation fins arranged on the upper part or the sides of the devices, and this results in a complicated structure.

### SUMMARY OF THE INVENTION

In view of the problems described above, the object of this invention is to provide a socket having a simple configuration capable of efficiently cooling an IC device, a circuit component having the socket and an information processing system having the circuit component.

In order to achieve the object described above, according to a first aspect of the invention, there is provided a socket comprising a body, probes arranged on the body and in electrical contact with the circuit component, and an opening formed in the body in the direction crossing the probes, wherein the probes are partly exposed to the opening.

According to a second aspect of the invention, there is provided a socket comprising a body having a component mounting surface to mount the circuit component, probes arranged on the body and in electrical contact with the circuit component and a heat conductive member arranged on the surface of the socket far from the component mounting surface and in contact with the probes.

According to a third aspect of the invention, there is provided a socket comprising a body having a component mounting surface to mount the circuit component, probes arranged on the body and in electrical contact with the circuit component, an opening formed in the body in the direction crossing the probes, and at least a through hole formed in the body to connect the opening with the component mounting surface.

According to a fourth aspect of the invention, there is provided a socket comprising a body having a component mounting surface to mount the circuit component, probes arranged on the body and in electrical contact with the circuit component and at least a groove formed on the component mounting surface facing the circuit component.

According to a fifth aspect of the invention, there is provided a socket comprising a body having a component mounting surface to mount the circuit component, at least a probe arranged on the body and in electrical contact with the circuit component and a plurality of slits formed on the side surfaces of the body.

According to a sixth aspect of the invention, there is provided a circuit component comprising a socket including a socket body formed with a mounting surface on which to mount a circuit element, probes in electrical contact with the circuit element and an opening formed in the socket body in the direction crossing the probes, and the circuit element mounted on the mounting surface and connected to the probes.

According to a seventh aspect of the invention, there is provided a circuit component comprising a socket including a socket body having a mounting surface to mount a circuit element, probes in electrical contact with the circuit element and a heat conductive member arranged on the surface of the socket body far from the mounting surface and in contact with the probes, and the circuit element mounted on the mounting surface and connected with the probes.

According to an eighth aspect of the invention, there is provided a circuit component comprising a socket including a socket body having a mounting surface to mount a circuit element, probes in electrical contact with the circuit element, an opening formed in the socket body in the direction crossing the probes and at least a through hole formed in the socket body to connect the opening to the mounting surface, and the circuit element connected with the probes.

According to a ninth aspect of the invention, there is provided a circuit component comprising a socket including a socket body formed with a mounting surface to mount a circuit element, probes in electrical contact with the circuit element and an opening formed in the socket body in the direction crossing the probes, and a circuit board connected with the socket.

According to a tenth aspect of the invention, there is provided an information processing system comprising a socket including a socket body having a mounting surface to mount a circuit element, probes in electrical contact with the circuit element and a heat conductive member arranged on the surface of the socket body far from the mounting surface and in contact with the probes, and a circuit board connected with the socket.

According to this invention, the probes of the socket or the socket itself can be easily cooled with a simple configuration, and therefore the IC device can be cooled efficiently. Also, due to a lack of fins or a fan over the upper surface of the device, the space above the the device can be reduced.

### BRIEF DESCRIPTION OF THE DRAWINGS

FIG. 1 is a top plan view of an IC socket on which an IC device is mounted according to a first embodiment of the invention.

FIG. 2 is a schematic sectional view taken in line A-A′ in FIG. 1.

FIG. 3 is a diagram showing an example of the contact probe used in the embodiments of the invention.

FIG. 4 is a diagram showing a modification of the first embodiment.

FIG. 5 is a diagram showing another modification of the first embodiment.

FIG. 6 is a diagram showing an IC socket according to a second embodiment of the invention.

FIG. 7 is a top plan view showing an IC socket according to a third embodiment of the invention.

FIG. 8 is a schematic sectional view taken in line B-B′ in FIG. 7.

FIG. 9 is a diagram showing a modification of the third embodiment.

FIG. 10 is a schematic sectional view taken in line C-C′ in FIG. 9.

FIG. 11 is a diagram showing another modification of the third embodiment.

FIG. 12 is a diagram showing a fourth embodiment of the invention.

FIG. 13 is a diagram showing a modification of the fourth embodiment of the invention.

FIG. 14 is a diagram showing an example of the information processing system embodying the invention.

FIG. 15 is a diagram showing a fifth embodiment of the invention.

### DESCRIPTION OF THE PREFERRED EMBODIMENTS

Embodiments of the invention are explained below with reference to the drawings.

### First Embodiment

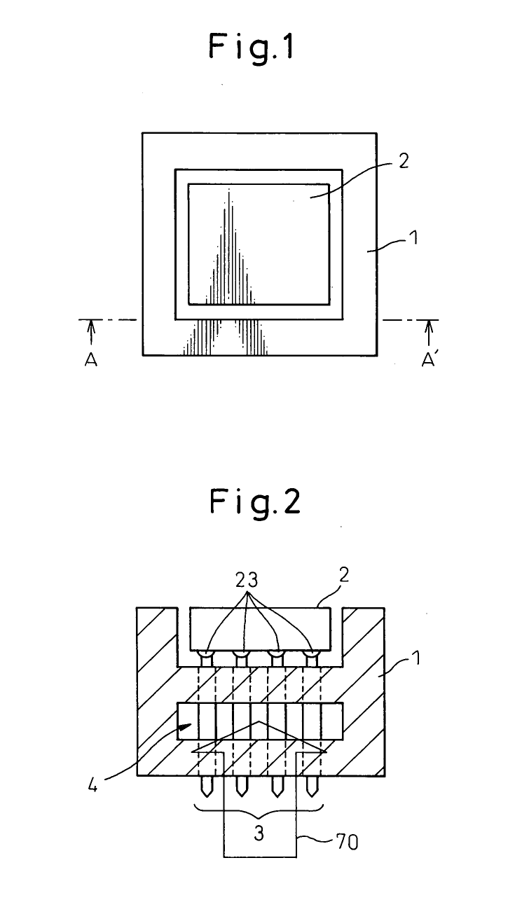

FIG. 1 is a top plan view of a socket according to a first embodiment of the invention, and FIG. 2 a schematic sectional view taken in line A-A′ in FIG. 1. FIGS. 1 and 2 show an IC socket 1 with a device such as an IC (integrated circuit) or a LSI (large scale integration), i.e. an IC device 2. The socket according to this embodiment is used for a test to check the operation of the IC device. Also, this socket may be combined with an IC device as a circuit component included in an information processing system.

The IC socket 1 is formed in a size somewhat larger than the IC device 2 and has an upper surface on which the IC device 2 can be mounted. As shown in FIG. 2, the IC socket has a multiplicity of contact probes 3 connected to electrode pads 23 formed on the lower surface of the IC device 2. Recently, the number of the electrode pads 23 has reached the order of several thousands, which in turn has increased the number of the contact probes to several thousands. In FIG. 2, however, only four contact probes 3 are shown.

The IC socket 1 is mounted on a printed circuit board (not shown) used for applying a test signal or a source voltage. The IC socket is connected to a circuit pattern of the printed circuit board. One end of each contact probe 3 is connected to the corresponding electrode pad 23. The other end of each contact probe 3 is connected to the test signal terminal or power terminal formed on the printed circuit board. When the IC device 2 is actually set on the IC socket 1, the contact probes 3 are pressed against the printed circuit board by the IC device 2. For this purpose, a means (not shown) is used to apply pressure on the upper surface of the IC device 2.

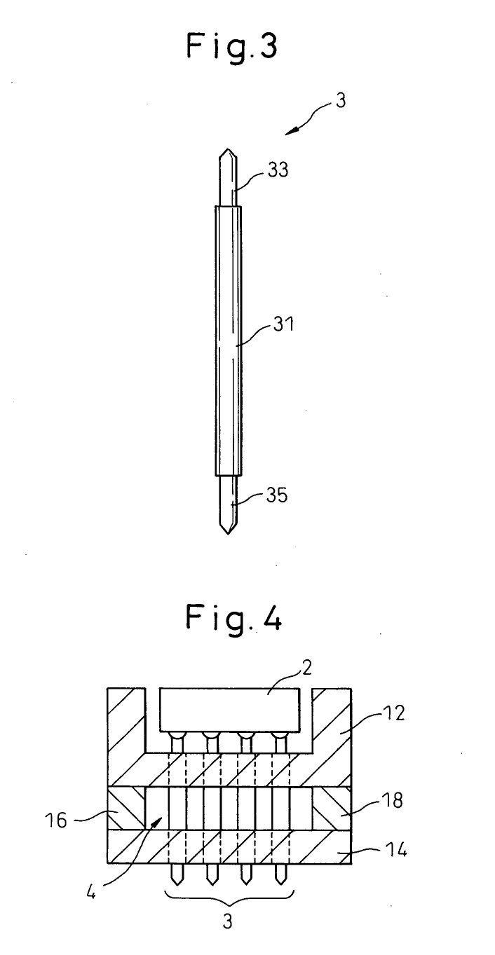

An example of the contact probe 3 used with the IC socket 1 is shown in FIG. 3. The contact probe 3 shown in FIG. 3, which is known as POGO Pin, includes an outer cylinder 31, and plungers 33, 35 projected from the ends of the outer cylinder 31 and movable in the outer cylinder 31. The plungers 33, 35 are prevented from coming off from the outer cylinder 31 by stoppers arranged on the inner wall of the outer cylinder 31. Further, a coil spring is arranged in the middle of the outer cylinder 31 to apply an outward force to the plungers 33, 35 arranged at the ends of the outer cylinder 31. The contact probe 3 electrically connects an electrode terminal with another by the reaction of the coil spring when the plungers 33, 35 are pressed against the electrode terminals. A plunger, which is a terminal of the contact probe, may be arranged only at one end. Further, the forward end of each plunger may be formed in an arbitrary shape.

The IC socket 1 according to this embodiment has a slit 4 for exposing a part of each contact probe 3. As shown in FIG. 2, the slit 4 forms a through space from one side to the opposed side of the IC socket 1, so that the intermediate portion of the outer cylinder of every contact probe of the IC socket 1 is exposed. A cooling air 70 is flowed by a blower (not shown) through the slit 4 to cool the contact probes 3 directly. As a result, the heat flowing from the electrode pads 23 of the device 2 to the contact probes 3 can be quickly passed to the air.

A more efficient cooling operation can be performed by supplying a cooling liquid to the slit 4. In this case, the cooling liquid or the outer cylinder of the probe is required to be insulative. If the cooling liquid is used, the slit 4 is sealed and is not required to be as large as shown in FIG. 2. The openings of the slit 4 may be closed by walls having two holes through which pipes are passed to supply and discharge the cooling liquid.

Further, as shown in FIG. 4, the socket may be formed of an upper member 12 on which the device is mounted, a lower member 14, and a pair of side walls 16, 18 in opposed relation to each other. A pair of side walls 16, 18 may be interposed between the upper member 12 and the lower member 14 to form the slit 4.

Though the slit 4 is formed through the socket and a pair of the side walls are open, the slit 4 may alternatively have four openings made in the side walls. In the IC socket shown in FIG. 4, the side walls 16, 18 may be replaced with four poles at the four corners between the lower member 14 and the upper member to open the four sides.

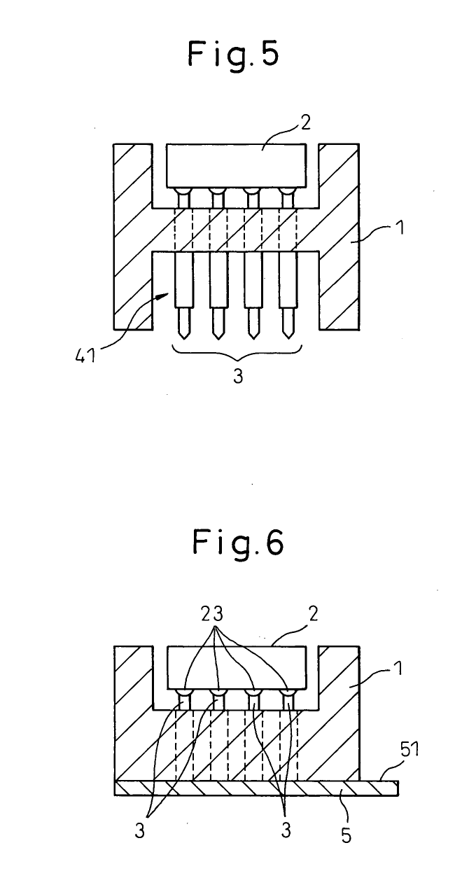

In the IC socket 1 shown in FIG. 5, the lower part of the slit 4 shown in FIG. 2 is open so that the slit 4 is formed as a notch 41. The notch 41 makes it possible to expose the intermediate and lower portion of the contact probes 3, and therefore the contact probes 3 can be cooled directly by blowing the cooling air to the notch 41. This modification can be formed also by omitting the lower member 14 and using the side walls 16, 18 shown in FIG. 4.

### Second Embodiment

In the IC devices recently developed, thousands of electrode pads are arranged and a comparatively small number of them are connected to a signal lines. In contrast, a greater number of the pads are connected to a power supply or the ground in order to supply a large amount of current to the IC device. Accordingly, a large number of probe contacts are connected to a power supply or the ground. The second embodiment of the invention is intended to cool a multiplicity of probe contacts connected to a power supply or the ground in order to efficiently cool the IC device.

FIG. 6 is a sectional view schematically showing an IC socket according to the second embodiment. The schematic sectional view of FIG. 6 is also taken in the same line as that of FIG. 2. An IC device 2 is mounted on the upper surface of the IC socket, and the electrode pads 23 of the IC device are in contact with the probe contacts 3 of the IC socket. A conductive metal plate 5 made of high heat conductivity metal, for example, copper, which is contact with the probe contacts connected to the ground, is arranged on the side of the IC socket 1 far from the side to mount IC device 2. By cooling an end portion 51 of the conductive metal plate 5, a multiplicity of the probe contacts connected to the ground are cooled. To cool the end portion 51 of the conductive metal plate 5, an arbitrary cooling means can be used. For example, cool air can be supplied or a Peltier element can be used. The signal probes are connected to a printed circuit board (not shown) through a through hole formed in the conductive metal plate 5, so that the signal probes are not electrically connected to the conductive metal plate 5. As an alternative, the portion of the conductive metal plate 5 corresponding to the signal probe contacts is formed with a large notch to secure the conduction between the signal probe contacts and the signal patterns of the printed circuit board. The conductive metal plate 5 can be connected to a power supply and the probe connected to the power supply can be cooled.

The first and second embodiments can be combined with each other. Specifically, the conductive metal plate shown in FIG. 6 is arranged on the lower surface of the socket according to the first embodiment shown in FIGS. 2, 4, 5, and grounding contact probes are grounded through the conductive metal plate. The cooling effect is increased by combining the first and second embodiments.

### Third Embodiment

According to a third embodiment, the top of the IC socket, on which the IC device is mounted, is communicated with the slit or notch of the IC socket of the first embodiment, so that the cooling air or the cooling liquid supplied to the slit 4 is applied also to the IC device 2.

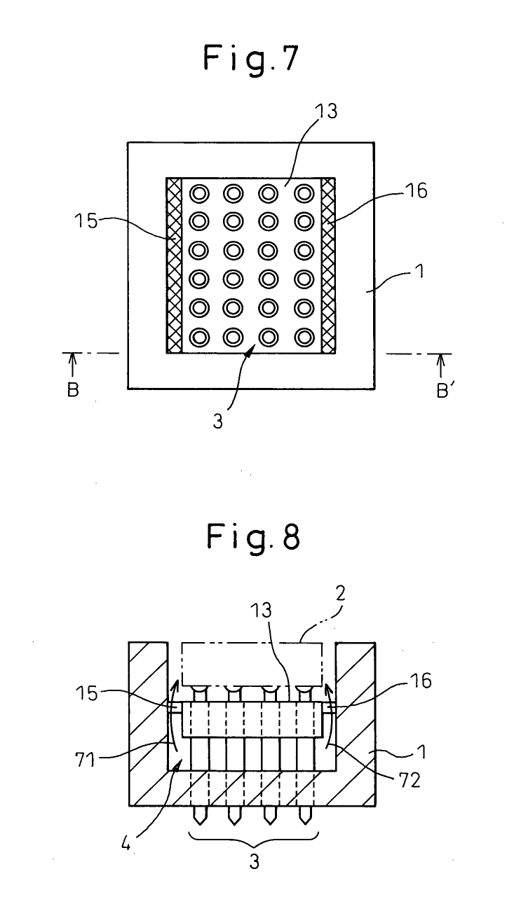

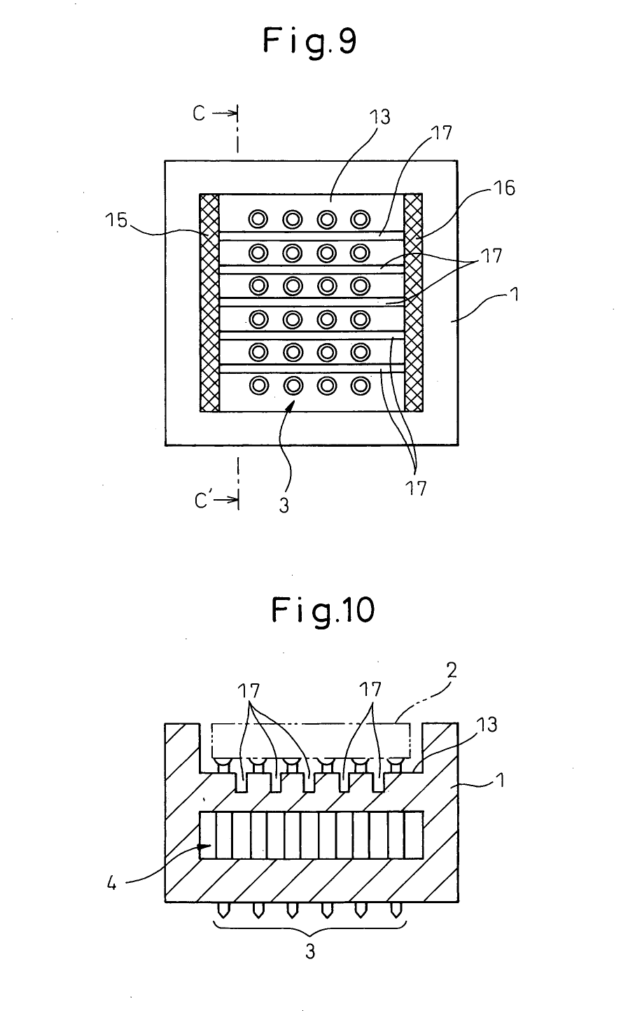

FIG. 7 is a top plan view of the socket 1 according to the third embodiment. The IC device mounting surface 13 of the IC socket is shown in FIG. 7. The forward ends of a multiplicity of the contact probes 3 to connect to the electrode pads of the IC device are exposed to the IC device mounting surface 13. According to the third embodiment, openings (extending vertically in FIG. 7 and communicating with the slit 4) are made in both sides of the IC device mounting surface 13. The openings extends vertically in FIG. 7 and communicates with slit 4. Meshes 15, 16 are arranged in the openings. As shown in FIG. 8 which is a schematic sectional view taken in line B-B′ in FIG. 7, the cooling air flows 71, 72 supplied to the slit 4 by a blower (not shown) flow to the IC device mounting surface 13 through the openings and the meshes 15, 16. The cooling air flowing to the IC device mounting surface 13 cools the forward ends of the contact probes 3 exposed on the IC device mounting surface 13 and the IC device 2 mounted thereon. The cooling effect is further increased by cooling the forward ends of the contact probes 3 and the IC device 2 as well as the middle portion of the contact probes 3. It is noted that the meshes 15, 16, which are intended to prevent the dust and dirt from dropping into the slit 4 through the openings, may be done without as desired. Also, the openings with the meshes arranged therein are not limited to the side portions of the IC device mounting surface, and at least one opening can be formed. Further, the sectional shape of the openings is not limited to the shown one, and can be such that the cooling air supplied from the slit 4 reaches the contact probes 3 and/or the IC device 2. For example, some of the grooves 17 (FIGS. 9, 10) explained below may be formed as the openings.

FIG. 9 shows a case in which grooves 17 are formed on the IC device mounting surface 13 of the socket 1, and FIG. 10 a sectional view taken in line C-C′ in FIG. 9. When the IC socket using a contact probe with movable plungers at the ends is used, the IC device is pressed against the IC socket to secure the contact between the probes and the contact points of the electrode pads or the printed circuit. As a result, the space between the IC device mounting surface of the socket 1 and the IC device is decreased. The decreased space may prevent the cooling air led to the IC device mounting surface 13 from smoothly flowing to the lower surface of the IC device. A plurality of grooves 17 connecting the spaces with the meshes 15, 16 are formed to secure the cooling air paths on the IC device mounting surface 13. The cooling air paths are secured by the grooves 17, even if the space between the IC device 2 and the IC device mounting surface 13 is narrowed by pressing the IC device 2 to the IC socket 1. Therefore, the contact probes in contact with the electrode pads of the IC device can be efficiently cooled together with the IC device itself.

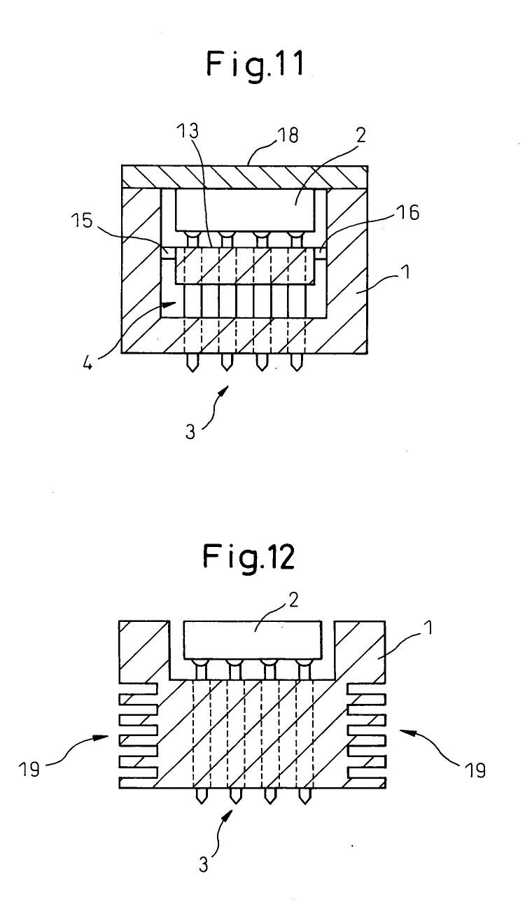

FIG. 11 shows a case in which a cooling liquid is used instead of the cooling air for the slit 4. The cooling liquid supplied to the slit 4 flows onto the IC device mounting surface 13 through the meshes 15, 16. To prevent an overflow of the cooling liquid, a lid 18 is placed on the IC socket. The lid 18 can be also used as a means for exerting pressure on the IC device to secure electrical contact between the pads of the IC device 2 and the contact probes 3. Further, the cooling liquid is required to be insulative, and the forward end portions of the contact probes 3 adapted for contact with the pads of the IC device 2 are preferably immovable contact portions formed integrally with the outer cylinder of the contact probes 3 to prevent the cooling liquid from intruding into the contact probes 3.

The third embodiment can be combined with a modification of the first embodiment shown in FIG. 4 or 5. Further, the combination of the first and second embodiments can be further combined with the third embodiment.

### Fourth Embodiment

FIG. 12 shows a fourth embodiment of the invention, in which the four side surfaces of the IC socket 1 are formed into fins 19. The fin-shaped side surfaces of the IC socket improve the heat radiation from the socket. Thus, a temperature increase of the socket is suppressed and the heat radiation effect promoted.

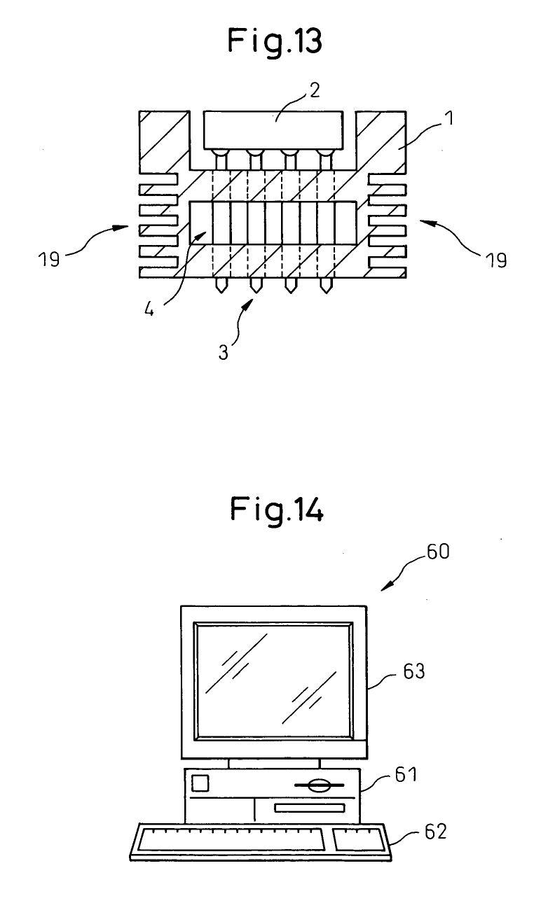

FIG. 13 shows a modification of the fourth embodiment of the invention, in which the side surfaces of the IC socket 1 of the first embodiment shown in FIGS. 1, 2 are formed into fins. As shown in FIG. 13, the side surfaces of the IC socket not having an opening are formed into fins. The fin-shaped side surfaces of the IC socket improves the heat radiation through the fins, so that the temperature increase of the socket is suppressed while promoting the radiation effect. Also in the modification (FIG. 4 or 5) of the first embodiment, the radiation effect is increased by forming fins on the side surfaces of the IC socket.

In the IC socket according to the second embodiment shown in FIG. 6, the four side surfaces thereof can be formed into fins to further improve the radiation effect. The third embodiment or the combination of the first to third embodiments can also be formed with fins on the side surfaces thereof to improve the radiation effect.

### Fifth Embodiment

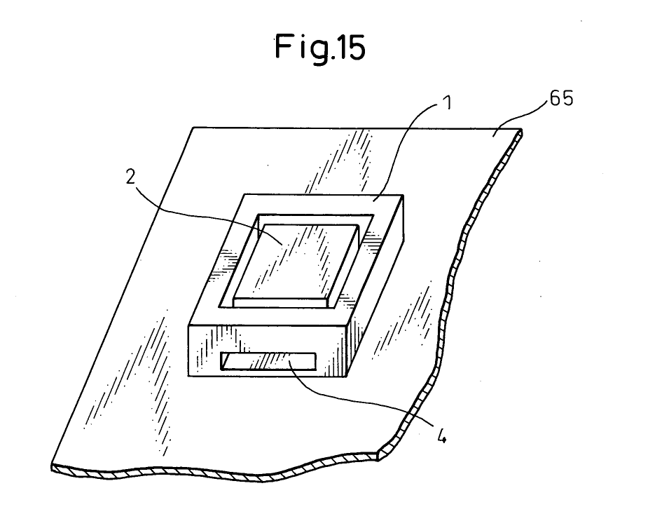

FIG. 14 shows an example of an information processing system according to this invention, and FIG. 15 a fifth embodiment of the invention applicable to a circuit component and further to the information processing system. The first to fourth embodiments refer to the socket used with an IC device test equipment, which socket can be used also as a circuit component of the information processing system.

FIG. 14 is a diagram showing a well-known personal computer (PC) as an example of the information processing system. The PC 60 includes a body 61, an input device 62 having a keyboard and a mouse, for example, and an output device 63 having a cathode ray tube (CRT) or a liquid crystal display. The body 61 includes a storage unit such as a hard disk, a flexible disk or an optical disk drive and further a main memory, a central processing unit (CPU) and various control circuits.

The main memory, the central processing unit (CPU) and the various control circuits are arranged on the printed circuit board 65 partly shown in FIG. 15. According to this embodiment, at least one of the main memory, the central processing unit (CPU) and the various control circuits mounted on the printed circuit board 65 is configured as an IC device mounted on the IC socket having the slit 4. A blower (not shown) for cooling the slit 4 can be mounted on the printed circuit board 65 or arranged at another point on the body 61.

As described above, when a circuit component used for the information processing system is configured as an IC socket with an IC device mounted thereon according to this embodiment, the IC device in operation can be easily cooled and proper heat control is possible. FIG. 15 shows the IC socket as a circuit component shown in the first embodiment of FIG. 1 or 2, and alternatively, the first to fourth embodiments or an arbitrary combination thereof can also be used.

What is claimed is:

1. A socket for mounting a circuit component, comprising:
a body in which an opening is formed;
a probe arranged on the body and in electrical contact with the circuit component, the probe is positioned as to be partly exposed to the opening.

2. A socket according to claim 1, wherein said opening is formed through the body.

3. A socket according to claim 1, wherein said opening is supplied with a liquid.

4. A socket for mounting a circuit component, comprising:
a body having a component mounting surface to mount the circuit component;
a probe arranged on the body and electrical contact with the circuit component; and
a heat conductive member arranged on a surface of the socket other than the component mounting surface and in contact with the probe.

5. A socket according to claim 4, wherein said heat conductive member has a electrical conductivity.

6. A socket according to claim 5, wherein said heat conductive member is in contact with the probe connected to a power terminal and/or a ground terminal of the circuit component.

7. A socket for mounting circuit component, comprising:
a body having a component mounting surface to mount the circuit component;
a probe arranged on the body and in electrical contact with the circuit component;
an opening formed in the body in the direction crossing the probe; and
a through hole formed in the body to connect the opening to the component mounting surface.

8. A socket according to claim 7, wherein a meshed member is arranged on said through hole.

9. A socket for mounting a circuit component, comprising:
a body having a component mounting surface to mount the circuit component;
a probe arranged on the body and in electrical contact with the circuit component; and
a groove formed on the component mounting surface facing the circuit component.

10. A socket according to claim 9, wherein a plurality of probes are arranged on said body; and
said groove is formed between adjacent ones of the probes.

11. A socket according to claim 9, further comprising:
an opening formed in the body in the direction crossing the probes; and
a through hole formed in said body to connect the opening to the component mounting surface; wherein,
one end of the groove is formed to direct to the through hole.

12. A socket according to claim 11, wherein,
a plurality of through holes are formed in said body, and
at least two of the through holes are formed at both sides of the circuit component, and the grooves are formed in such a manner as to connect the through holes in longitudinal direction.

13. A socket for mounting a circuit component, comprising:
a body having a component mounting surface to mount the circuit component;
a probe arranged on the body and in electrical contact with the circuit component; and
a plurality of slits formed on the side surfaces of the body.

14. A socket according to claim 13, wherein the body has an opening formed in the direction crossing the probe.

15. A circuit component comprising:
a socket including a body having a mounting surface to mount the circuit element, a probe in electrical contact with the circuit element and an opening formed in the body in the direction crossing the probe; and
the circuit element mounted on the mounting surface and connected to the probe.

16. A circuit component comprising:
a socket including a body having a mounting surface to mount a circuit element, a probe in electrical contact with the circuit element and a heat conductive member arranged on the other surface of the socket body opposite to the mounting surface and in contact with the probe; and
the circuit element mounted on the mounting surface and connected to the probe.

17. A circuit component comprising:
a socket including a body having a mounting surface to mount a circuit element, a probe in electrical contact with the circuit element, an opening formed in the socket body in the direction crossing the probe and a through hole formed in the socket body to connect the opening to the mounting surface; and
the circuit element mounted on the mounting surface and connected to the probe.

18. An information processing system comprising:
a circuit board;
a socket mounted onto said circuit board, and having a mounting surface;
a circuit element mounted onto said mounting surface;
a probe in electrical contact with the circuit element mounted on said mounting surface;
and an opening formed in the socket body in a direction crossing the probe.

19. An information processing system comprising:
a circuit board;
a socket mounted onto said circuit board having a mounting surface;
a circuit element mounted onto said mounting surface;
a probe in electrical contact with the circuit element mounted onto said mounting surface; and
a heat conductive member arranged on the surface of the socket body opposite to the mounting surface and in contact with the probe.

20. An information processing system comprising:
a circuit board;
a socket mounted onto said circuit board having a mounting surface;
a circuit element mounted onto said mounting surface;
a probe in electrical contact with the circuit element mounted on said mounting surface;
an opening formed in the socket body in a direction crossing the probe; and
a through hole formed in the socket body connecting the opening and the mounting surface.
